(19) United States
(12) Patent Application Publication
(10) Pub. No.: US 2007/0202710 A1
(43) Pub. Date: Aug. 30, 2007

(54) Method for fabricating semiconductor device using hard mask

(75) Inventors: Ki-Won Nam, Kyoungki-do (KR); Ky-Hyun Han, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/647,624

(22) Filed: Dec. 29, 2006

(30) Foreign Application Priority Data
Feb. 27, 2006 (KR) 2006-0018805
Dec. 1, 2006 (KR) 2006-0120793

(51) Int. Cl. H01L 21/31; H01L 21/469

(52) U.S. Cl. 438/787; 257/E21.231

(57) ABSTRACT

A method for fabricating a semiconductor device includes forming a layer to be etched, forming a hard mask pattern over the layer, and etching the layer to form a pattern. The hard mask pattern has an atomic percentage of a silicon-hydrogen bond varying with a thickness of the hard mask pattern.

### CROSS-REFERENCES TO RELATED APPLICATIONS

The present invention claims priority of Korean patent application numbers 10-2006-0018805 and 10-2006-0120793, filed on Feb. 27, 2006 and Dec. 1, 2006, respectively, which are incorporated by reference in their entirety.

### BACKGROUND OF THE INVENTION

The present invention relates to a method for fabricating a semiconductor device, and more particularly, to a method for fabricating a semiconductor device using a hard mask.

A polysilicon layer has been used as a hard mask due to lack of a photoresist margin to define a storage node contact hole during fabricating a dynamic random access memory (DRAM) device with a size of about 9 nm. However, the polysilicon layer induces a mask alignment during forming a subsequent storage node contact. Thus, after performing an additional process opening a storage node contact key box and defining the storage node contact hole, a process to remove the polysilicon layer used as the hard mask is added. Furthermore, the polysilicon layer exposed to an entire surface of a wafer may be used as a particle source during a cleaning process repeatedly performed.

It has been suggested to use a nitride-based thin film as the hard mask to overcome the above described limitations. However, hydrogen components existing inside a nitride layer for the hard mask or an inter-layer insulation layer may not be diffused out during forming the polysilicon layer for the storage node contact, but diffused to a silicon substrate. Accordingly, a transistor property of a peripheral circuit region may be changed.

A thin film having a small atomic percentage of hydrogen components may be used as a hard mask for a storage node contact to prevent a moisture penetration and diffuse out existing moisture. However, a top portion of the hard mask may be damaged due to a degradation of a self-aligned contact etch property of the storage node contact.

### SUMMARY OF THE INVENTION

Embodiments of the present invention are directed to provide a method for fabricating a semiconductor device suitable for increasing an etch margin during etching a pattern such as a storage node contact hole and obtaining a stable transistor property.

In accordance with an aspect of the present invention, there is provided a method for fabricating a semiconductor device, including: forming a layer to be etched; forming a hard mask pattern over the layer; and etching the layer to form a pattern, wherein the hard mask pattern has an atomic percentage of a silicon-hydrogen bond varying with a thickness of the hard mask pattern.

In accordance with another aspect of the present invention, there is provided a method for fabricating a semiconductor device, including: forming an insulation layer over a substrate where a landing plug is already formed; forming a hard mask pattern having an atomic percentage of a silicon-hydrogen bond varying with a thickness of the hard mask pattern over the insulation layer; and etching the insulation layer to form a storage node contact hole.

### BRIEF DESCRIPTION OF THE DRAWINGS

FIGS. 1A to 1C illustrate a method for fabricating a storage node contact hole of a semiconductor device in accordance with an embodiment of the present invention.

FIG. 2 illustrates a graph of an atomic percentage of a silicon-hydrogen (Si—H) varying with a thickness of a hard mask layer in accordance with another embodiment of the present invention.

### DESCRIPTION OF SPECIFIC EMBODIMENTS

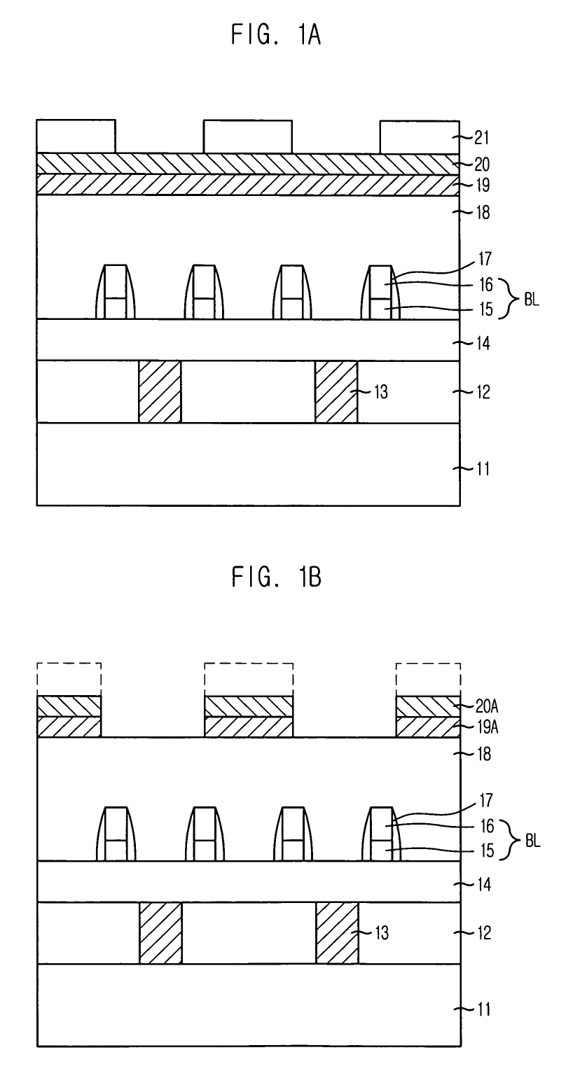

FIGS. 1A to 1C illustrate a method for fabricating a storage node contact hole of a semiconductor device in accordance with an embodiment of the present invention. As shown in FIG. 1A, a first insulation layer 12 is formed over an upper portion of a substrate 11 and then, a plurality of contact holes penetrating the first insulation layer 12 are formed. A plurality of landing plugs 13 filling the contact holes are formed between word lines (not shown). The landing plugs 13 include polysilicon.

A second insulation layer 14 is formed over the landing plugs 13 and the first insulation layer 12. Afterwards, a plurality of bit lines BL, each formed stacking a bit line tungsten layer 15 and a bit line hard mask 16, are formed over certain portions of the second insulation layer 14. A barrier metal layer can be formed beneath the bit line tungsten layer 15. The barrier metal layer includes a stack structure of titanium (Ti) and titanium nitride (TiN). The bit line hard mask 16 includes a nitride layer.

An insulation layer for spacers is formed over upper portions of the bit lines BL. An etch back process is performed to the insulation layer to form a plurality of spacers 17 for the bit lines BL over sidewalls of the bit lines BL.

A third insulation layer 18 is formed over an entire surface of the above resulting structure including the bit lines BL and then, planarized. The first insulation layer 12, the second insulation layer 14, and particularly, the third insulation layer 18 include an oxide layer such as borophosphosilicate glass (BPSG) layer. The oxide layer includes hydrogen components.

A hard mask layer is formed over a planarized portion of the third insulation layer 18. The hard mask layer is a structure which has an atomic percentage of a silicon-hydrogen (Si—H) bond varying with a thickness. The atomic percentage of the Si—H bond is minimized from a bottom portion of the hard mask layer to a certain thickness of the hard mask layer, and increased in a remaining portion of the hard mask layer. The portion where the atomic percentage of the Si—H bond is minimized is referred to as a first hard mask layer 19, and the portion where the atomic percentage of the silicon-hydrogen bond is increased is referred to as a second hard mask layer 20.

The first hard mask layer 19 has a thickness capable of making an atomic percentage of the hydrogen components minimized in the layer and hydrogen existing in the insulation layers and the lower structure beneath the first hard mask layer 19 smoothly diffused out. The second hard mask layer 20 has a thickness capable of strengthening a self-aligned contact (SAC) etch property during etching a subsequent storage node contact hole.

A silane (SiH₄) gas, a nitrous oxide (N₂O) gas, and a helium (He) gas are used to form the first hard mask layer 19 and second hard mask layers 20. Particularly, an ammonia (NH₃) gas is additionally used to form the second hard mask layer 20.

In more detail, the first hard mask layer 19 is formed to a thickness ranging from about 500 Å to about 1,000 Å using a mixture gas obtained adding the N₂O gas and the He gas to the SiH₄ gas at a temperature of about 400° C. A flow rate of the SiH₄ gas ranges from about 50 sccm to about 200 sccm. A flow rate of the N₂O gas ranges from about 50 sccm to about 300 sccm. A flow rate of the He gas ranges from about 1,000 sccm to about 3,000 sccm.

After the first hard mask layer 19 is formed to the certain thickness, the second hard mask layer 20 is formed additionally using the NH₃ gas. In more detail, the second hard mask layer 20 is formed to a thickness ranging from about 500 Å to about 1,000 Å using a mixture gas obtained adding the N₂O gas, the He gas, and the NH₃ gas to the SiH₄ gas. A flow rate of the SiH₄ gas ranges from about 50 sccm to about 200 sccm. A flow rate of the N₂O gas ranges from about 50 sccm to about 300 sccm. A flow rate of the He gas ranges from about 1,000 sccm to about 3,000 sccm. A flow rate of the NH₃ gas ranges from about 100 sccm to about 200 sccm.

As described above, the SiH₄ gas, the N₂O gas, and the He gas are commonly used during forming the first hard mask layer 19 and the second hard mask layer 20. The NH₃ gas is additionally used to form the second hard mask layer 20.

There is a difference in an atomic percentage of the Si—H bond between the first hard mask layer 19 and the second hard mask layer 20. For instance, since the NH₃ gas is additionally used to form the second hard mask layer 20, the second hard mask layer 20 has the atomic percentage of the Si—H bond higher than the first hard mask layer 19. The second hard mask layer 20 can have a silicon-rich property due to the increased atomic percentage of the Si—H bond. Accordingly, an etch selectivity can be increased. However, since the first hard mask layer 19 has the atomic percentage of the Si—H bond smaller than the second hard mask layer 20, the hydrogen components in the first hard mask layer 19 can be decreased. Accordingly, a hydrogen penetration can be reduced.

A photoresist pattern 21 is formed over the first hard mask layer 19 and the second hard mask layer 20.

As shown in FIG. 1B, the second hard mask layer 20 and the first hard mask layer 19 are sequentially etched using the photoresist pattern 21 to form a second hard mask pattern 20A and a first hard mask pattern 19A. As a result, a hard mask pattern is formed in a stack structure of the first hard mask pattern 19A and the second hard mask pattern 20A. The photoresist pattern 21 and remaining polymers are removed using an oxygen gas at the same camber.

As shown in FIG. 1C, the third insulation layer 18 is etched using the hard mask pattern as an etch barrier to form a plurality of storage node contact holes 22 exposing surfaces of the landing plugs 13. The patterned third insulation layer is denoted with a reference numeral 18A.

The etching process to form the storage node contact holes 22 includes performing a self-aligned contact etching process using the hard mask pattern as the etch barrier. Since the second hard mask pattern 20A has the strengthened self-aligned contact property, loss on top portions of the storage node contact holes 22 can be minimally produced during performing the etching process. Accordingly, a uniform loss on the second hard mask pattern 20A can be generated to an entire surface of a wafer.

During forming the storage node contact holes 22, the self-aligned contact etching process etches the second hard mask pattern 20A and thus, the second hard mask pattern 20A does not remain. Only the first hard mask pattern 19A remains and performs a role of an etch barrier during the self-aligned contact etching process. Since the atomic percentage of the Si—H bond is minimized when the first hard mask pattern 19A is initially formed, hydrogen can be easily diffused out performing a high temperature thermal process during forming a subsequent polysilicon layer for a storage node contact plug. Furthermore, since the first hard mask pattern 19A contains the low atomic percentage of hydrogen, a change in a threshold voltage property can be minimized.

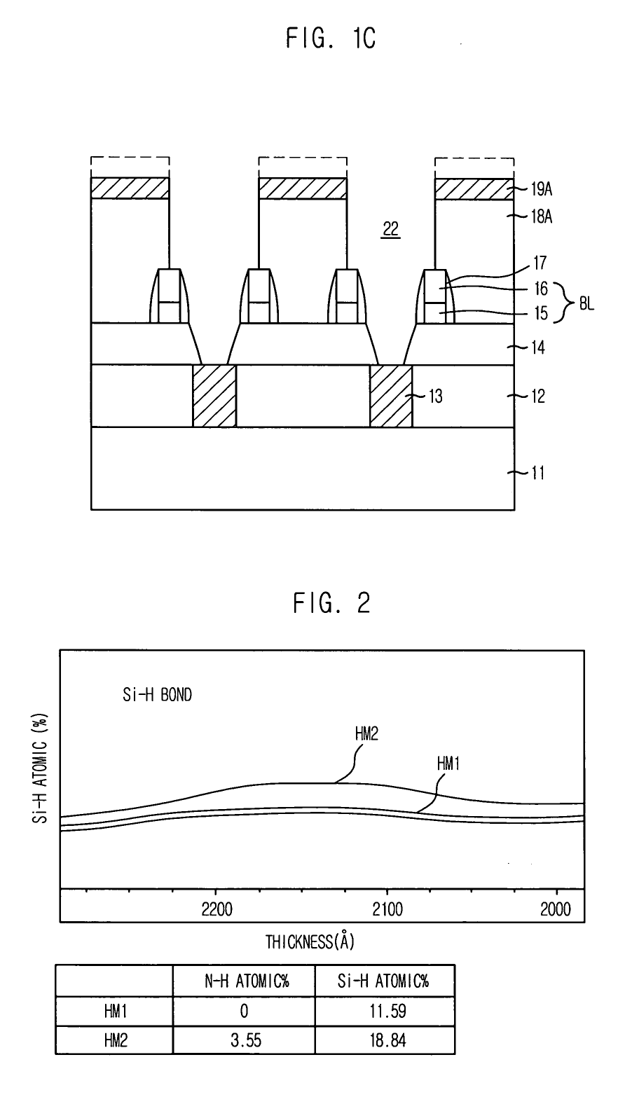

FIG. 2 illustrates a graph of an atomic percentage of a silicon-hydrogen (Si—H) bond varying with a thickness of a hard mask layer in accordance with another embodiment of the present invention. An atomic percentage of an atomic bond in a first hard mask layer is compared with the atomic percentage of the atomic bond in a second hard mask layer. Reference denotations ‘HM1’ and ‘HM2’ denote the first hard mask layer and the second hard mask layer, respectively.

The second hard mask layer HM2 has high atomic percentages of a nitrogen-hydrogen (N—H) bond and the Si—H bond than the first hard mask layer HM1. For instance, the atomic percentage of the Si—H bond in the second hard mask layer HM2 is about 18.84 while the atomic percentage of the Si—H bond in the first hard mask layer HM1 is about 11.59. Accordingly, the first hard mask layer HM1 has the atomic percentage of the Si—H bond lower than the second hard mask layer HM2. In addition, the atomic percentage of the N—H bond of the second hard mask layer HM2 is about 3.55. Accordingly, the second hard mask layer HM2 has the atomic percentage of the N—H bond higher than the first hard mask layer HM1.

Since the second hard mask layer HM2 contains the atomic percentage of the Si—H bond higher than the first hard mask layer HM1, the second hard mask layer HM2 becomes a silicon-rich layer. Accordingly, a hydrogen penetration can be reduced.

As described above, during forming the hard mask pattern to form the storage node contact holes, a self-aligned contact etching property can be improved using a physical property varying with a thickness of the hard mask layer. As a result, top portions of the storage node contact holes cannot be damaged, and a threshold voltage can be minimally changed. Accordingly, the process can be stably performed.

Although the hard mask pattern used to form the storage node contact holes is exemplified, this embodiment of the present invention can be applied to a hard mask pattern used to form a pattern including a contact hole, a gate, and a bit line. Since the hard mask pattern is formed changing the atomic percentage of the Si—H bond with the thickness of the hard mask pattern, an etching characteristic associated with the self-aligned contact can be improved. This improvement allows less damage on the pattern.

As described above, during forming the hard mask layer, certain portions of the hard mask layer are removed through a physical property and an etch property varying with the thickness of the hard mask layer. Accordingly, a self-aligned contact etching margin is increased, thereby obtaining a stable transistor property.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a layer to be etched;
forming a hard mask pattern over the layer; and
etching the layer to form a pattern,
wherein the hard mask pattern has an atomic percentage of a silicon-hydrogen bond varying with a thickness of the hard mask pattern.

2. The method of claim 1, wherein the hard mask pattern includes a first hard mask layer having a low atomic percentage of the silicon-hydrogen bond and a second hard mask layer having a high atomic percentage of the silicon-hydrogen bond.

3. The method of claim 2, wherein the first hard mask layer and the second hard mask layer are formed using a silane (SiH₄) gas, a nitrous oxide (N₂O) gas, and a helium (He) gas, wherein an ammonia (NH₃) gas is additionally used during forming the second hard mask layer.

4. The method of claim 3, wherein when forming the first hard mask layer and the second hard mask layer, a flow rate of the SiH₄ gas ranges from about 50 sccm to about 200 sccm; a flow rate of the N₂O gas ranges from about 50 sccm to about 300 sccm; and a flow rate of the He gas ranges from about 1,000 sccm to about 3,000 sccm.

5. The method of claim 4, wherein when forming the second hard mask layer, a flow rate of the NH₃ gas ranges from about 100 sccm to about 200 sccm.

6. The method of claim 2, wherein the first hard mask layer and the second hard mask layer are formed to substantially the same thickness.

7. The method of claim 6, wherein the thickness ranges from about 500 Å to about 1,000 Å.

8. The method of claim 1, wherein the layer to be etched includes an oxide-based layer containing hydrogen.

9. A method for fabricating a semiconductor device, comprising:
forming an insulation layer over a substrate where a landing plug is already formed;
forming a hard mask pattern having an atomic percentage of a silicon-hydrogen bond varying with a thickness of the hard mask pattern over the insulation layer; and
etching the insulation layer to form a storage node contact hole.

10. The method of claim 9, wherein the hard mask pattern includes a first hard mask layer having a low atomic percentage of the silicon-hydrogen bond and a second hard mask layer having a high atomic percentage of the silicon-hydrogen bond.

11. The method of claim 10, wherein the first hard mask layer and the second hard mask layer are formed using a silane (SiH₄) gas, a nitrous oxide (N₂O) gas, and a helium (He) gas, wherein an ammonia (NH₃) gas is additionally used during forming the second hard mask layer.

12. The method of claim 11, wherein when forming the first hard mask layer and the second hard mask layer, a flow rate of the SiH₄ gas ranges from about 50 sccm to about 200 sccm; a flow rate of the N₂O gas ranges from about 50 sccm to about 300 sccm; and a flow rate of the He gas ranges from about 1,000 sccm to about 3,000 sccm.

13. The method of claim 12, wherein when forming the second hard mask layer, a flow rate of the NH₃ gas ranges from about 100 sccm to about 200 sccm.

14. The method of claim 10, wherein the first hard mask layer and the second hard mask layer are formed to substantially the same thickness.

15. The method of claim 14, wherein the thickness ranges from about 500 Å to about 1,000 Å.

16. The method of claim 10, wherein the forming of the hard mask pattern includes:
forming the first hard mask layer containing a low atomic percentage of the silicon-hydrogen bond and the second hard mask layer containing a high atomic percentage of the silicon-hydrogen bond;
forming a photoresist pattern over the second hard mask layer;
etching the second hard mask layer and the first hard mask layer; and
removing the photoresist pattern.

17. The method of claim 16, wherein the removing of the photoresist pattern includes using an oxygen gas.

18. The method of claim 9, wherein the insulation layer includes an oxide-based layer containing hydrogen.
